(19) United States
(12) Patent Application Publication
(10) Pub. No.: US 2026/0076185 A1
(43) Pub. Date: Mar. 12, 2026

(54) BACKSIDE DUAL DIELECTRIC FILL FOR BETTER THERMAL CONDUCTIVITY

(71) Applicant: INTERNATIONAL BUSINESS MACHINES CORPORATION, ARMONK, NY (US)

(72) Inventors: Sarabjot Singh, Albany, NY (US); Tao Li, Slingerlands, NY (US); Ruilong Xie, Niskayuna, NY (US); Qianwen Chen, Chappaqua, NY (US); Joshua M. Rubin, Albany, NY (US)

(21) Appl. No.: 18/830,870

(22) Filed: Sep. 11, 2024

(51) Int. Cl. H01L 23/373; H01L 23/532; H01L 27/088; H01L 29/06; H01L 29/417; H01L 29/423; H01L 29/775; H01L 29/786

(52) U.S. Cl. CPC H10W 40/25; H10D 30/6729; H10D 84/83; H10W 20/47; H10D 30/43; H10D 30/6735; H10D 30/6757; H10D 62/121

(57) ABSTRACT

According to the embodiment of the present invention, a semiconductor device comprises a first nanodevice including a plurality of first transistors. The first nanodevice includes a first placeholder. A backside interlayer dielectric (BILD) layer is in direct contact with a first portion of sidewalls of the first placeholder. The BILD layer is comprised of a first dielectric material. A backside thermal dissipation dielectric is in direct contact with a backside surface of the BILD layer. The backside thermal dissipation dielectric is comprised of a second dielectric material.

### BACKGROUND

The present invention relates generally to the field of microelectronics, and more particularly to a semiconductor device structure, and a method for forming a semiconductor device.

A nanosheet (NS) is the lead device architecture in continuing CMOS scaling. However, nanosheet technology has shown issues when scaling down such that as the devices become smaller and closer together, they are interfering with each other. Furthermore, as the devices become smaller and closer together, forming the connections to a backside power network is becoming more difficult.

### SUMMARY

According to the embodiment of the present invention, a semiconductor device comprises a first nanodevice including a plurality of first transistors. The first nanodevice includes a first placeholder. A backside interlayer dielectric (BILD) layer is in direct contact with a first portion of sidewalls of the first placeholder. The BILD layer is comprised of a first dielectric material. A backside thermal dissipation dielectric is in direct contact with a backside surface of the BILD layer. The backside thermal dissipation dielectric is comprised of a second dielectric material.

According to the embodiment of the present invention, a semiconductor device comprises a first nanodevice including a plurality of first transistors and a second nanodevice including a plurality of second transistors. The first nanodevice includes a first placeholder. The second nanodevice is located adjacent to and parallel to the first nanodevice. The second nanodevice includes a second placeholder. A BILD layer is in direct contact with a first portion of sidewalls of the first placeholder. The BILD layer is comprised of a first dielectric material. A backside thermal dissipation dielectric is in direct contact with a backside surface of the BILD layer. The backside thermal dissipation dielectric is comprised of a second dielectric material.

According to the embodiment of the present invention, a semiconductor device comprises a first nanodevice including a plurality of first transistors and a second nanodevice including a plurality of second transistors. The first nanodevice includes a first placeholder. The second nanodevice is located adjacent to and parallel to the first nanodevice. The second nanodevice includes a second placeholder. A BILD layer is in direct contact with a first portion of sidewalls of the first placeholder. The BILD layer is comprised of a first dielectric material. A backside thermal dissipation dielectric is in direct contact with a backside surface of the BILD layer. The backside thermal dissipation dielectric is comprised of a second dielectric material. A backside source/drain contact has two separate horizontal frontside surfaces. A first horizontal frontside surface of the two separate horizontal frontside surfaces is in direct contact with the backside surface of the BILD layer.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates a top-down view of a plurality of nanodevices, in accordance with the embodiment of the present invention.

FIGS. 2-4 illustrate cross sections X, Y₁, and Y₂, respectively, of the plurality of nanodevices after interlayer dielectric (ILD) deposition, nanosheet formation, shallow trench isolation (STI) region formation, STI liner formation, gate formation, gate spacer and inner spacer formation, bottom dielectric isolation (BDI) layer formation, source/drain formation, source/drain contact formation, gate contact formation, placeholder formation, underlying Si layer formation, backside interlayer dielectric (BILD) layer formation, back-end-of-line (BEOL) layer formation, carrier wafer formation, carrier wafer flip, substrate removal, and CMP, in accordance with the embodiment of the present invention.

FIGS. 5-7 illustrate cross sections X, Y₁, and Y₂, respectively, of the plurality of nanodevices after selective recessing of the BILD layer, in accordance with the embodiment of the present invention.

FIGS. 8-10 illustrate cross sections X, Y₁, and Y₂, respectively, of the plurality of nanodevices after the formation of a backside thermal dissipation dielectric, in accordance with the embodiment of the present invention.

FIGS. 11-13 illustrate cross sections X, Y₁, and Y₂, respectively, of the plurality of nanodevices after the formation of a lithography mask layer, a first trench, and a second trench, in accordance with the embodiment of the present invention.

FIGS. 14-16 illustrate cross sections X, Y₁, and Y₂, respectively, of the plurality of nanodevices after the formation of a first backside source/drain contact and a second backside source/drain contact, in accordance with the embodiment of the present invention.

FIGS. 17-19 illustrate cross sections X, Y₁, and Y₂, respectively, of the plurality of nanodevices after the formation of a first backside power rail (BPR), a second BPR, an additional BILD layer, and a backside power delivery network (BSPDN), in accordance with the embodiment of the present invention.

FIGS. 20-22 illustrate cross sections X, Y₁, and Y₂, respectively, of the plurality of nanodevices after the formation of the backside thermal dissipation dielectric, in accordance with the embodiment of the present invention.

FIGS. 23-25 illustrate cross sections X, Y₁, and Y₂, respectively, of the plurality of nanodevices after the formation of a first conductive metal fill, a second conductive metal fill, and CMP, in accordance with the embodiment of the present invention.

FIGS. 26-28 illustrate cross sections X, Y₁, and Y₂, respectively, of the plurality of nanodevices after the formation of the lithography mask layer, the first trench, and the second trench, in accordance with the embodiment of the present invention.

FIGS. 29-31 illustrate cross sections X, Y₁, and Y₂, respectively, of the plurality of nanodevices after the formation of the first backside source/drain contact and the second backside source/drain contact, in accordance with the embodiment of the present invention.

FIGS. 32-34 illustrate cross sections X, Y₁, and Y₂, respectively, of the plurality of nanodevices after the formation of the first BPR, the second BPR, the additional BILD layer, and the BSPDN, in accordance with the embodiment of the present invention.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

References in the specification to “one embodiment,” “an embodiment,” “an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art to affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “formed on,” or “formed atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be a direct or indirect positional relationship. As an example of an indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both an indirect “connection” and a direct “connection. ”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about”means within 10, 9, 8, 7, 6, 5, 4, 3, 2, or 1% of the reported numerical value.

Various processes which are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout.

Currently in CMOS circuits, Aluminum nitride (AlN) is used as a bonding material due to its heat dissipation properties. By merely using AlN as a bonding material, heat generated by the semiconductor device cannot be adequately dissipated, which can be responsible for overheating of the semiconductor device.

By forming a backside dual dielectric comprised of AlN and SiC or AlN and SiOC, thermal dissipation may be improved from a backside of a silicon wafer. Additionally, using AlN as a thermal dissipation liner may prevent shorting in the semiconductor device. The present invention does not require that all advantages need to be incorporated into every embodiment of the invention.

The present invention is directed to forming a backside dual dielectric comprised of a backside interlayer dielectric (BILD) layer (e.g., SiC or SiOC) and AlN. The backside dual dielectric is formed through a multistage processing, where the first stage etches a portion of the BILD layer to expose a sacrificial placeholder. The second stage deposits a dielectric material in a space created by the removal of the portion of the BILD layer to form an AlN dielectric fill above the BILD layer. The third stage forms a first trench by etching a portion of the AlN dielectric fill and a shallow trench isolation (STI) region liner, and a second trench by etching a portion of the AlN dielectric fill and the STI region liner. The fourth stage fills the first trench and the second trench with a conductive metal to form a first backside source/drain contact and a second backside source/drain contact, respectively. The fifth stage forms a first backside power rail (BPR) above the first backside source/drain contact and the second backside source/drain contact, a second BPR above the AlN dielectric fill, and an additional BILD layer above the AlN dielectric fill, the first backside source/drain contact, and the second backside source/drain contact. The sixth stage forms a back-end-of-line (BEOL) layer above the first BPR, the second BPR, and the additional BILD layer.

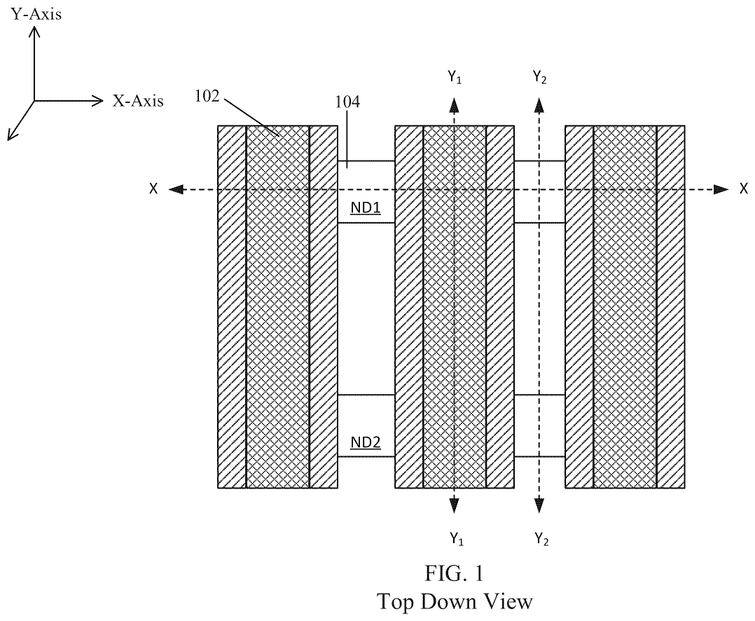

FIG. 1 illustrates a top-down view of a plurality of nanodevices ND1, ND2, in accordance with the embodiment of the present invention. The adjacent and parallel devices include a first nanodevice ND1 including a plurality of first transistors and a second nanodevice ND2 including a plurality of second transistors. Cross-section X is a cross section perpendicular to the gates along the horizontal axis of the first nanodevice ND1. Cross-section Y₁ is a cross section parallel to the gates in the gate region 102 across the plurality of nanodevices ND1, ND2. Cross-section Y₂ is a cross section parallel to the gates in the source/drain region 104 across the plurality of nanodevices ND1, ND2. It may be appreciated that the embodiment of the present invention is not limited to nanodevices ND1, ND2 and that other devices including, but not limited to, nanosheet transistors, FinFET, nanowire, and a planar device may also be used.

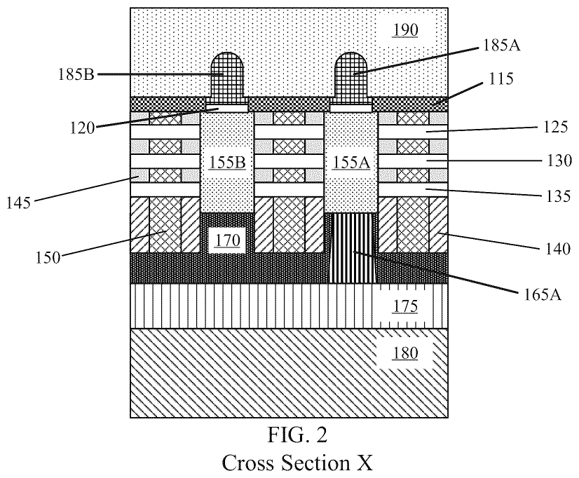

FIGS. 2-4 illustrate cross sections X, Y₁, and Y₂, respectively, of the plurality of nanodevices ND1, ND2 after interlayer dielectric (ILD) 170 deposition, nanosheet 125, 130, 135 formation, STI region 195 formation, STI liner 200 formation, gate 150 formation, gate spacer 140 and inner spacer 145 formation, bottom dielectric isolation (BDI) layer 115 formation, source/drain 155A, 155B, 155C formation, source/drain contact 165A, 165B formation, gate contact 190A formation placeholder 185A, 185B, 185C formation, underlying Si layer 120 formation, BILD layer 190 formation, BEOL layer 175 formation, carrier wafer 180 formation, carrier wafer 180 flip, substrate removal, and CMP, in accordance with the embodiment of the present invention. The plurality of nanodevices ND1, ND2 include an STI region 195, an STI liner 200, an underlying Si layer 120, a first nanosheet 125, a second nanosheet 130, and a third nanosheet 135. A substrate (not shown) and an etch stop layer (not shown) can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate (not shown). In some embodiments, the substrate (not shown) includes both semiconductor materials and dielectric materials. The substrate (not shown) may also comprise an organic semiconductor or a layered semiconductor such as, for example, Si/SiGe, a silicon-on-insulator or a SiGe-on-insulator. A portion or the entire substrate (not shown) may also be comprised of an amorphous, polycrystalline, or monocrystalline. The substrate (not shown) and the etch stop layer (not shown) may be doped, undoped or contain doped regions and undoped regions therein. A portion of an underlying substrate layer (not shown) is selectively removed and a material (e.g., SiGe) is deposited in a space created by the removal of the portion of the underlying substrate layer (not shown) to form the first placeholder 185A, the second placeholder 185B, and the third placeholder 185C (i.e., the second placeholder in the claims). The first nanodevice ND1 includes the first placeholder 185A and the second nanodevice includes the third placeholder 185C. The remaining portion of the underlying substrate layer (not shown) can be, for example, the underlying Si layer 120.

The first sacrificial layer (not shown) is formed directly atop an underlying substrate layer (not shown). The first nanosheet 125 is formed directly atop the first sacrificial layer (not shown). The second sacrificial layer (not shown) is formed directly atop the first nanosheet 125. The second nanosheet 130 is formed directly atop the second sacrificial layer (not shown). The third sacrificial layer (not shown) is formed directly atop the second nanosheet 130. The third nanosheet 135 is formed directly atop the third sacrificial layer (not shown). The first sacrificial layer (not shown), the second sacrificial layer (not shown), and the third sacrificial layer (not shown) are hereinafter referred to as the plurality of sacrificial layers (not shown). In addition, the first nanosheet 125, the second nanosheet 130, and the third nanosheet 135 are hereinafter referred to as the plurality of nanosheets 125, 130, 135. The plurality of sacrificial layers (not shown) may be comprised of, for example, SiGe, where Ge is about 35%. The plurality of nanosheets 125, 130, 135 may be comprised of, for example, Si. The number of nanosheets and the number of sacrificial layers described above are not intended to be limiting, and it may be appreciated that in the embodiment of the present invention the number of nanosheets and the number of sacrificial layers may vary. After formation of the plurality of nanosheets 125, 130, 135 and the plurality of sacrificial layers (not shown), together the nanosheet stack, the nanosheet stack (comprising alternative Si and SiGe layers) may be further patterned using conventional lithography and etching processes. After nanosheet stack formation and patterning, the STI region 195 and STI liner 200 is formed by dielectric filling, CMP, and dielectric recess. The STI liner 200 can be comprised of, for example, SiN.

A dummy gate material is deposited and then patterned to form dummy gates (not shown), followed by gate spacer 140 and BDI layer 115 formation by a conformal dielectric liner deposition followed by anisotropic etch. Then, the nanosheet stack at the S/D region 104 is recessed, followed by indentation of sacrificial layers (not shown) and inner spacer 145 formation. Then, the first source/drain 155A, the second source/drain 155B, and the third source/drain 155C (i.e., the second source/drain in the claims) are epitaxially grown over exposed sidewalls of the plurality of nanosheets 125, 130, 135, followed by ILD 170 deposition and CMP to remove a dummy gate hard mask (not shown). Then, the sacrificial layers (not shown) are removed, followed by gate 150 formation. The first source/drain 155A, the second source/drain 155B, and the third source/drain 155C are formed directly atop the underlying Si layer 120.

The first source/drain 155A, the second source/drain 155B, and the third source/drain 155C can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

In FIG. 2, the ILD 170 is formed directly atop the first source/drain 155A and the second source/drain 155B, and surrounds one side of the gate spacer 140. In FIG. 4, the ILD 170 is formed directly atop the second source/drain 155B, the third source/drain 155C, the STI region 195, and the STI liner 200.

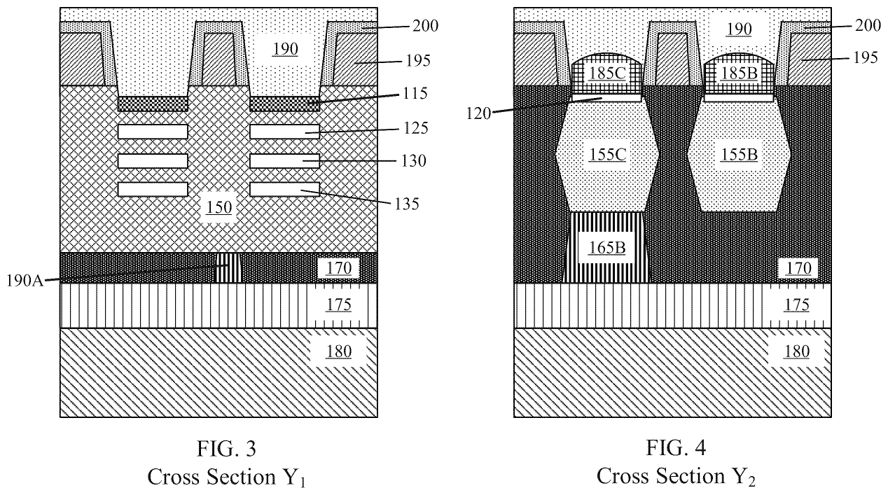

In FIG. 2, a gate material is deposited in the space created by the removal of the plurality of sacrificial layers (not shown) and directly atop the third nanosheet 135 to form a replacement gate (i.e., the gate 150). In FIG. 3, the gate material is deposited in the space created by the removal of the plurality of sacrificial layers (not shown), and directly atop the third nanosheet 135, the STI region 195, and the STI liner 200 to form the gate 150. The gate 150 can be comprised of, for example, a gate dielectric liner, such as a high-k dielectric like HfO2, ZrO2, HfLaOx, etc., and work function layers, such as TiN, TiAlC, TiC, etc., and conductive metal fills, like W.

A plurality of trenches (not shown) formed during middle-of-line (MOL) patterning are filled with a conductive metal (e.g., including a silicide liner, such as Ni, Ti, NiPt, an adhesion metal liner, such as TiN and conductive metal fill, such as W, Co, or Ru) to form the first source/drain contact 165A, the second source/drain contact 165B, and the gate contact 190A. In FIG. 2, the first source/drain contact 165A is located directly atop the first source/drain 155A. In FIG. 3, the gate contact 190A is located directly atop the gate 150. In FIG. 4, the second source/drain contact 165B is located directly atop the third source/drain 155C. The BEOL layer 175 may contain multiple metal layers and vias in between. In FIG. 2, the BEOL layer 175 is formed directly atop the first source/drain contact 165A and the ILD 170. In FIG. 3, the BEOL layer 175 is formed directly atop the ILD 170 and the gate contact 190A. In FIG. 4, the BEOL layer 175 is formed directly atop the second source/drain contact 165B and the ILD 170. In FIGS. 2-4, the carrier wafer 180 is formed directly atop the BEOL layer 175 by bonding processes (e.g., oxide-oxide bonding).

The carrier wafer 180 is flipped and the carrier wafer 180 becomes a handler wafer. The BILD layer 190 may be comprised of, for example, SiC or SiOC. In FIG. 2, the BILD layer 190 is deposited directly atop the BDI layer 115, the first placeholder 185A, and the second placeholder 185B. In FIG. 3, the BILD layer 190 is deposited directly atop the BDI layer 115 and the STI liner 200. In FIG. 4, the BILD layer 190 is deposited directly atop the second placeholder 185B, the third placeholder 185C, and the STI liner 200.

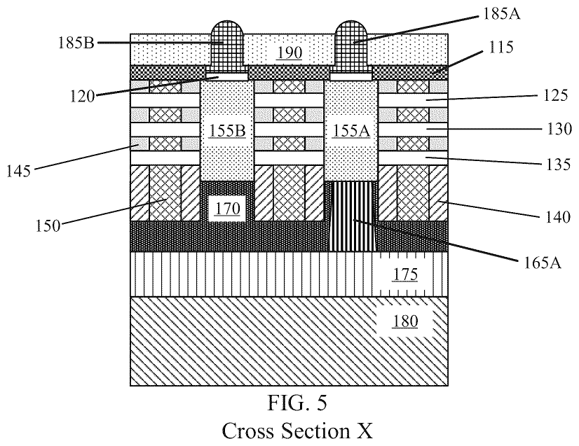

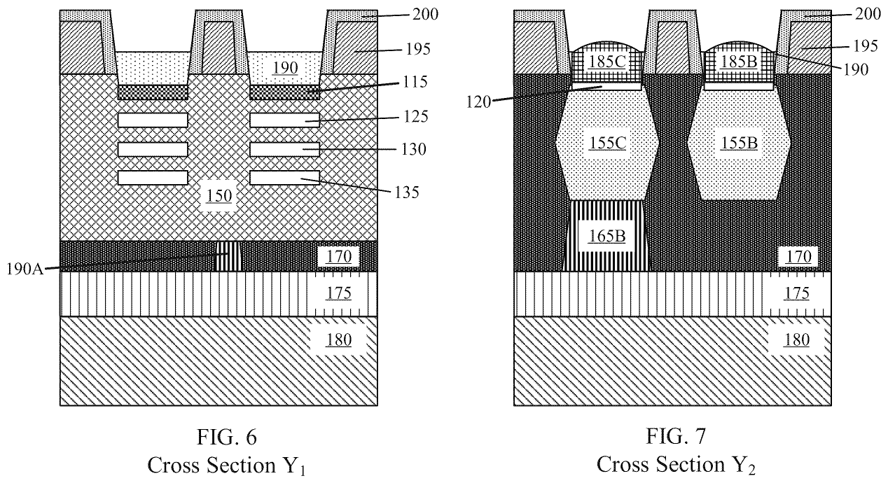

FIGS. 5-7 illustrate cross sections X, Y₁, and Y₂, respectively, of the plurality of nanodevices ND1, ND2 after selective recessing of the BILD layer 190, in accordance with the embodiment of the present invention. A portion of the BILD layer 190 is selectively removed by, for example, CMP. In FIGS. 5 and 7, the selective removal of the portion of the BILD layer 190 exposes a top surface and upper sidewalls of the first placeholder 185A, the second placeholder 185B, and the third placeholder 185C.

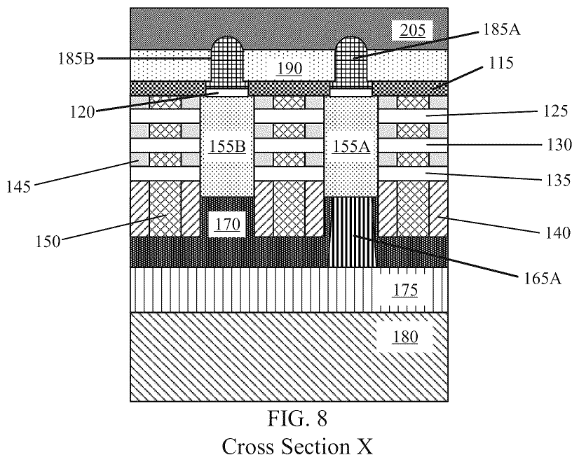

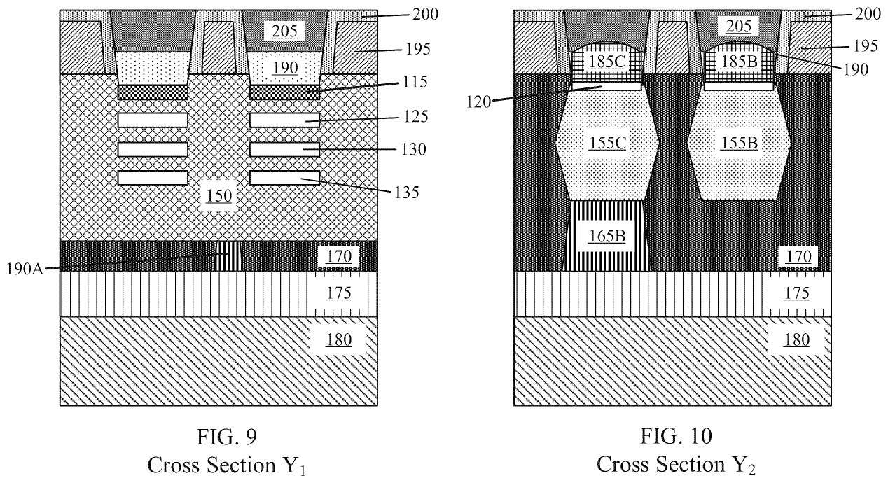

FIGS. 8-10 illustrate cross sections X, Y₁, and Y₂, respectively, of the plurality of nanodevices ND1, ND2 after the formation of a backside thermal dissipation dielectric 205, in accordance with the embodiment of the present invention. A dielectric material is deposited in a space created by the selective removal of the portion of the BILD layer 190 to form the backside thermal dissipation dielectric 205. In FIG. 8, the backside thermal dissipation dielectric 205 is located directly atop the BILD layer 190, the first placeholder 185A, and the second placeholder 185B. In FIG. 9, the backside thermal dissipation dielectric 205 is located directly atop the BILD layer 190. In FIG. 10, the backside thermal dissipation dielectric 205 is located directly atop the second placeholder 185B and the third placeholder 185C.

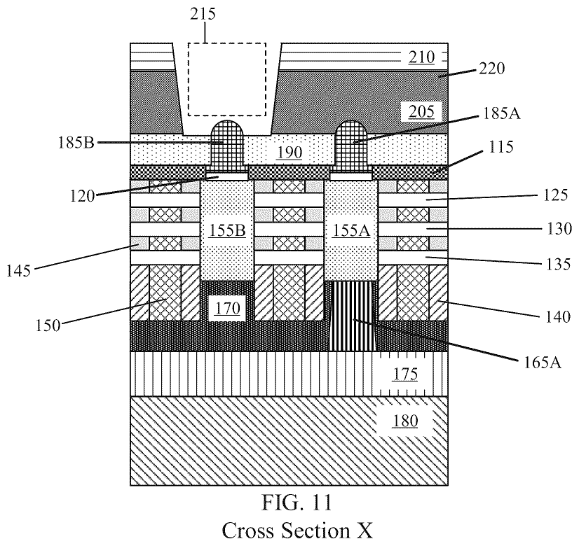

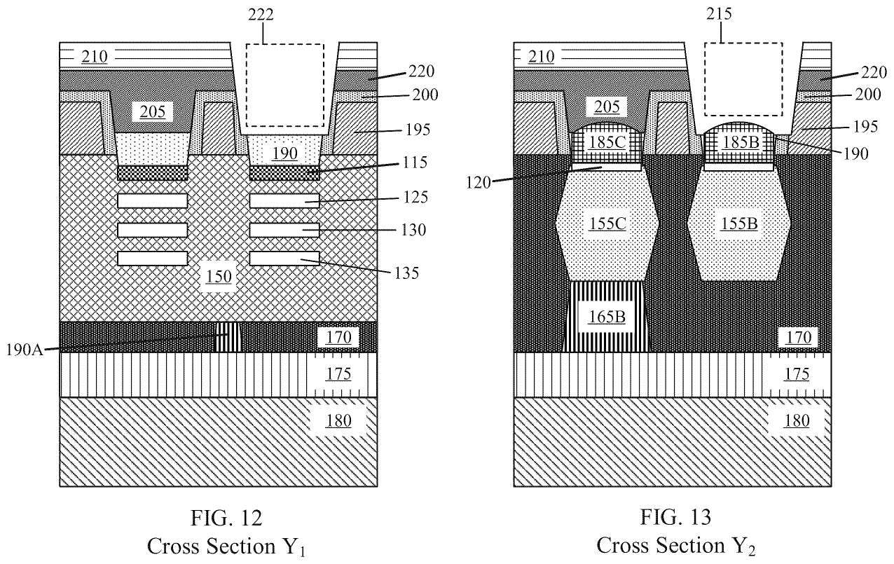

FIGS. 11-13 illustrate cross sections X, Y₁, and Y₂, respectively, of the plurality of nanodevices ND1, ND2 after the formation of a lithography mask layer 210, a first trench 215, and a second trench 222, in accordance with the embodiment of the present invention. An additional backside thermal dissipation dielectric 220 is deposited directly atop the backside thermal dissipation dielectric 205 and the STI liner 200. It may be appreciated that the additional backside thermal dissipation dielectric 220 and the backside thermal dissipation dielectric 205 form a contiguous unitary structure comprised of a same material and are therefore together referred to as “the backside thermal dissipation dielectric” in the claims. The lithography mask layer 210 may be, for example, an organic planarization layer (OPL). In FIG. 11, the lithography mask layer 210 is deposited and then patterned directly atop the additional backside thermal dissipation dielectric 220 to expose a portion of the underlying additional backside thermal dissipation dielectric 220. The exposed portion of the underlying additional backside thermal dissipation dielectric 220 is etched by, for example, RIE to form the first trench 215. A bottom surface of the first trench 215 exposes a top surface and upper sidewalls of the second placeholder 185B. In FIG. 12, the lithography mask layer 210 is deposited and then patterned directly atop the additional backside thermal dissipation dielectric 220 to expose a portion of the underlying additional backside thermal dissipation dielectric 220. The exposed portion of the underlying additional backside thermal dissipation dielectric 220 and the STI liner 200 are etched by, for example, RIE to form the second trench 222. A bottom surface of the second trench 222 exposes a top surface of the BILD layer 190. In FIG. 13, the lithography mask layer 210 is deposited and then patterned directly atop the additional backside thermal dissipation dielectric 220 to expose a portion of the underlying additional backside thermal dissipation dielectric 220. The exposed portion of the underlying additional backside thermal dissipation dielectric 220, the STI liner 200, and the STI region 195 are etched by, for example, RIE to form the first trench 215. A bottom surface of the first trench 215 exposes a top surface and upper sidewalls of the second placeholder 185B. In FIGS. 11-13, the lithography mask layer 210 is formed by depositing, for example, an OPL material in a spin-on coating process.

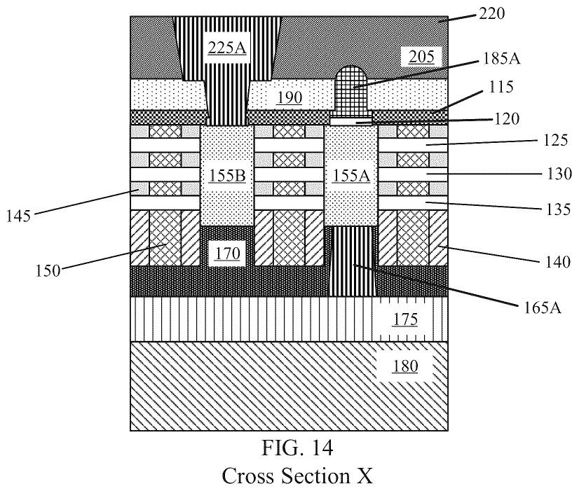

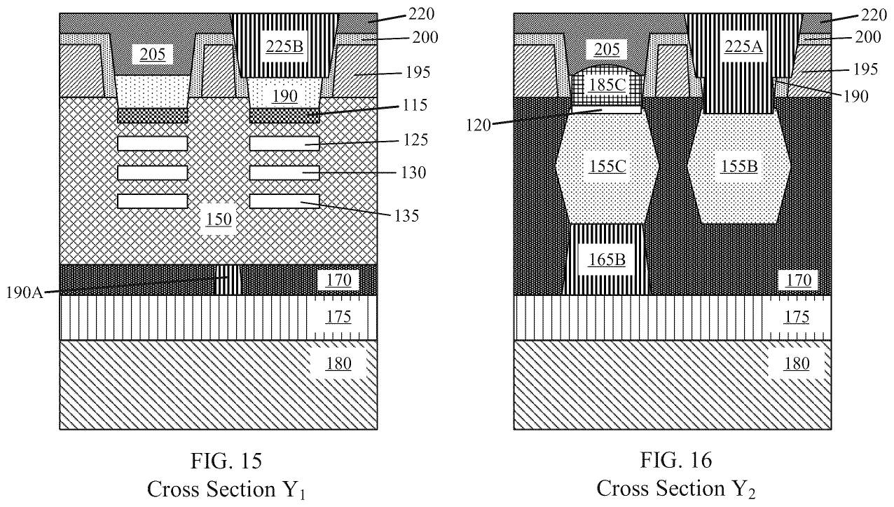

FIGS. 14-16 illustrate cross sections X, Y₁, and Y₂, respectively, of the plurality of nanodevices ND1, ND2 after the formation of a first backside source/drain contact 225A and a second backside source/drain contact 225B, in accordance with the embodiment of the present invention. The lithography mask layer 210 (FIGS. 11-13) and the second placeholder 185B (FIGS. 11 and 13) are removed. The first trench 215 (FIGS. 11 and 13) and the second trench 222 (FIG. 12) are filled with a conductive metal (e.g., including a silicide liner, such as Ni, Ti, NiPt, an adhesion metal liner, such as TiN and conductive metal fill, such as W, Co, or Ru) to form the first backside source/drain contact 225A (i.e., the backside source/drain contact in the claims) and the second backside source/drain contact 225B. In FIGS. 14 and 16, the first backside source/drain contact 225A is located directly atop the second source/drain 155B. In FIG. 15, the second backside source/drain contact 225B is located directly atop the BILD layer 190.

The BILD layer 190 is in direct contact with a first portion of sidewalls of the first placeholder 185A. The BILD layer 190 is comprised of a first dielectric material, which may be Silicon oxycarbide. The backside thermal dissipation dielectric 205 is in direct contact with a backside surface of the BILD layer 190. The backside thermal dissipation dielectric 205 is comprised of a second dielectric material, which may be Aluminum nitride. The backside thermal dissipation dielectric 205 is also in direct contact with a second portion of the sidewalls of the first placeholder 185A, a backside surface of the first placeholder 185A, and a backside surface of the third placeholder 185C. The underlying Si layer 120 is in direct contact with a frontside surface of the first placeholder 185A and the third placeholder 185C. The first placeholder 185A and the third placeholder 185C progressively narrow from the frontside surface of the first placeholder 185A and the third placeholder 185C to the backside surface of the first placeholder 185A and the third placeholder 185C, respectively.

The first backside source/drain contact 225A has two separate horizontal frontside surfaces. A first horizontal frontside surface of the two separate horizontal frontside surfaces is in direct contact with the backside surface of the BILD layer 190. A second horizontal frontside surface of the two separate horizontal frontside surfaces is connected to the second source/drain 155B.

The first source/drain 155A and the third source/drain 155C are in direct contact with a frontside surface of the underlying Si layer 120. The first source/drain contact 165A and the second source/drain contact 165B are connected to a frontside surface of the first source/drain 155A and the third source/drain 155C, respectively. The BEOL layer 175 is in direct contact with a frontside surface of the first source/drain contact 165A and the second source/drain contact 165B. The first source/drain 155A and the third source/drain 155C are electrically connected to the BEOL layer 175 via the first source/drain contact 165A and the second source/drain contact 165B, respectively.

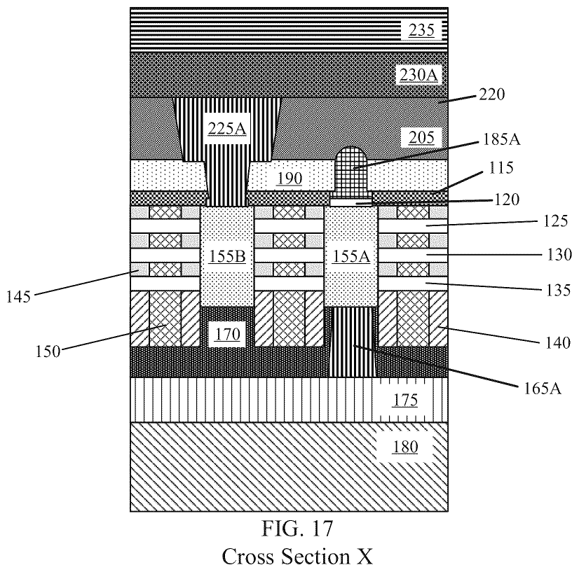

FIGS. 17-19 illustrate cross sections X, Y₁, and Y₂, respectively, of the plurality of nanodevices ND1, ND2 after the formation of a first backside power rail (BPR) 230A, a second BPR 230B, an additional BILD layer 240, and a backside power delivery network (BSPDN) 235, in accordance with the embodiment of the present invention. The first BPR 230A (i.e., the BPR in the claims) and the second BPR 230B are patterned using conventional lithography and etching processes, followed by metallization (e.g., Cu, Co or Ru fill with adhesion liner such as TiN). The first BPR 230A has a positive supply voltage. The second BPR 230B has a negative supply voltage.

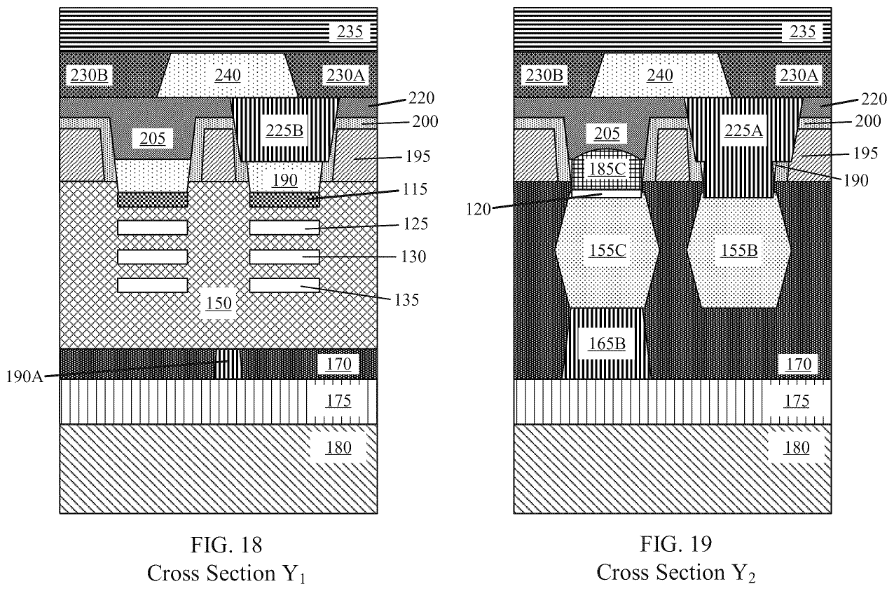

In FIG. 17, the first BPR 230A is formed directly atop the additional backside thermal dissipation dielectric 220 and the first backside source/drain contact 225A. A top surface of the first backside source/drain contact 225A is connected to the first BPR 230A. In FIG. 18, an additional BILD layer 240 is deposited directly atop the additional backside thermal dissipation dielectric 220 and the second backside source/drain contact 225B. The first BPR 230A is formed directly atop the additional backside thermal dissipation dielectric 220 and the second backside source/drain contact 225B. A bottom surface of the first BPR 230A is in direct contact with the additional backside thermal dissipation dielectric 220 and the second backside source/drain contact 225B. The second BPR 230B is formed directly atop the additional backside thermal dissipation dielectric 220. A bottom surface of the second BPR 230B is in direct contact with the additional backside thermal dissipation dielectric 220. In FIG. 19, an additional BILD layer 240 is deposited directly atop the additional backside thermal dissipation dielectric 220 and the first backside source/drain contact 225A. The first BPR 230A is formed directly atop the additional backside thermal dissipation dielectric 220 and the first backside source/drain contact 225A. A bottom surface of the first BPR 230A is in direct contact with the additional backside thermal dissipation dielectric 220 and the first backside source/drain contact 225A. The second BPR 230B is formed directly atop the additional backside thermal dissipation dielectric 220. A bottom surface of the second BPR 230B is in direct contact with the additional backside thermal dissipation dielectric 220.

In FIG. 17, the BSPDN 235 is formed directly atop the first BPR 230A. In FIGS. 18-19, the BSPDN 235 is formed directly atop the first BPR 230A, the second BPR 230B, and the additional BILD layer 240.

The first BPR 230A is in direct contact with a backside surface of the additional backside thermal dissipation dielectric 220. The additional backside thermal dissipation dielectric 220 is flush with a single horizontal backside surface of the first backside source/drain contact 225A.

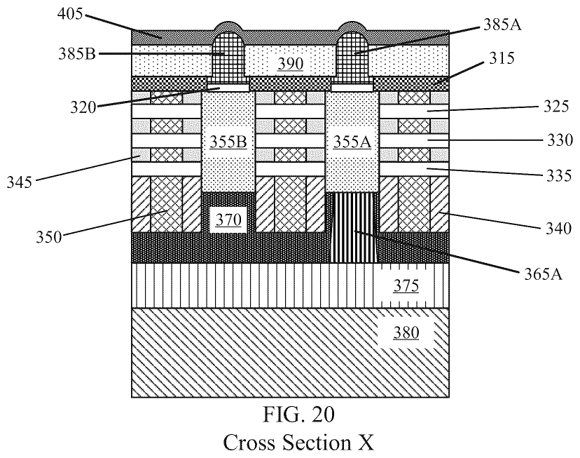

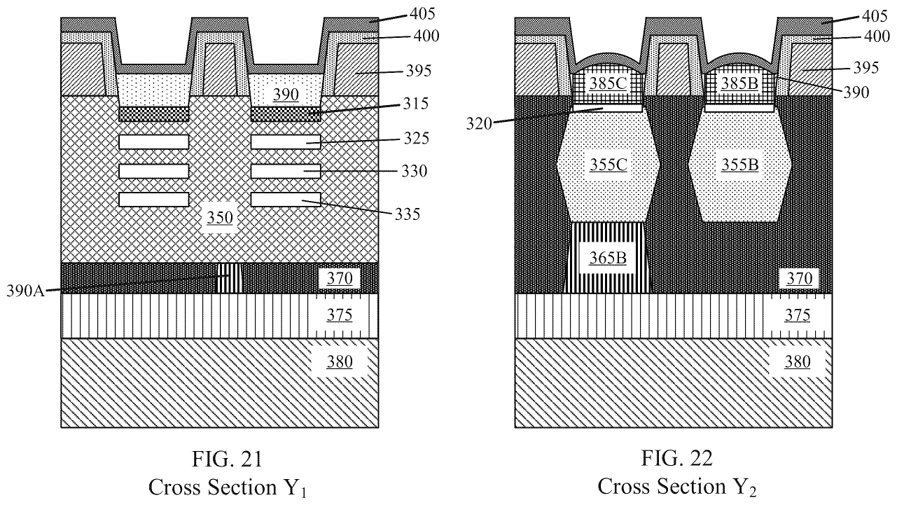

FIGS. 20-22 illustrate cross sections X, Y₁, and Y₂, respectively, of the plurality of nanodevices ND1, ND2 after the formation of the backside thermal dissipation dielectric 405, in accordance with the embodiment of the present invention. In FIG. 20, the backside thermal dissipation dielectric 405 is located directly atop the BILD layer 390, the first placeholder 385A, and the second placeholder 385B. In FIG. 21, the backside thermal dissipation dielectric 405 is located directly atop the BILD layer 390 and directly atop and along sidewalls of the STI liner 400. In FIG. 10, the backside thermal dissipation dielectric 405 is located directly atop the second placeholder 385B and the third placeholder 385C and directly atop and along sidewalls of the STI liner 400. In FIGS. 20-22, the backside thermal dissipation dielectric 405 is continuous and conformal with respect to the BILD layer 390, the first placeholder 385A, the second placeholder 385B, and the STI liner 400.

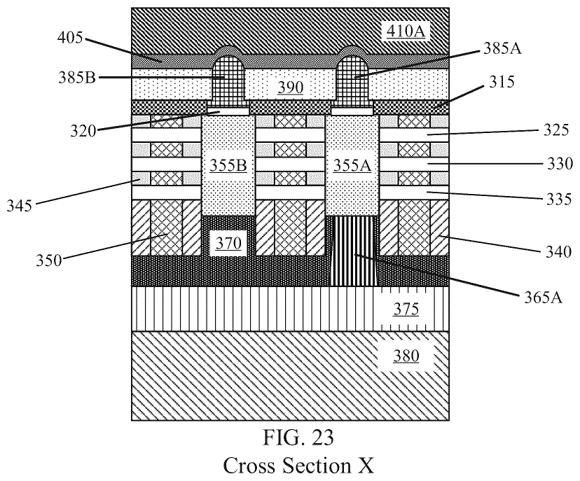

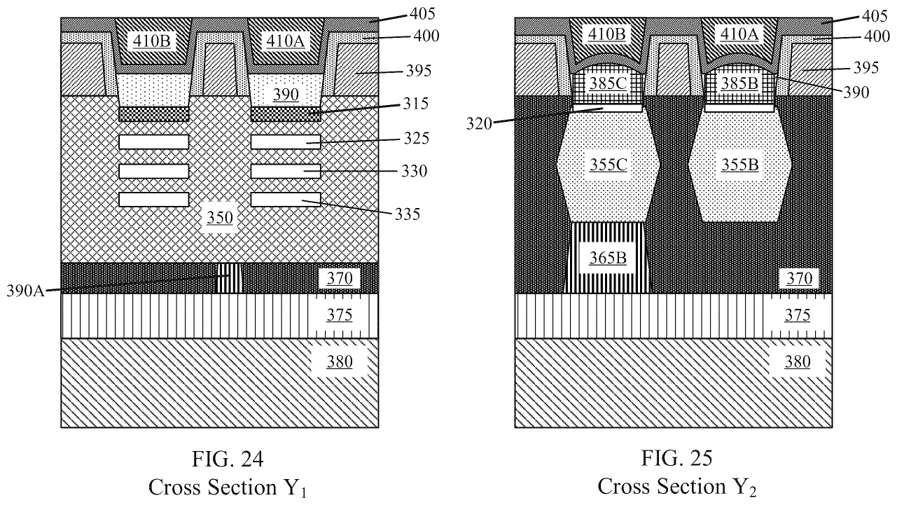

FIGS. 23-25 illustrate cross sections X, Y₁, and Y₂, respectively, of the plurality of nanodevices ND1, ND2 after the formation of a first conductive metal fill 410A, a second conductive metal fill 410B, and CMP, in accordance with the embodiment of the present invention. A different conductive metal (e.g., such as W, Co, Al, or Ru) is deposited directly atop and along sidewalls of the backside thermal dissipation dielectric 405 to form the first conductive metal fill 410A (i.e., the conductive metal fill in the claims) and the second conductive metal fill 410B. A portion of the first conductive metal fill 410A and the second conductive metal fill 410B are selectively removed by, for example, CMP.

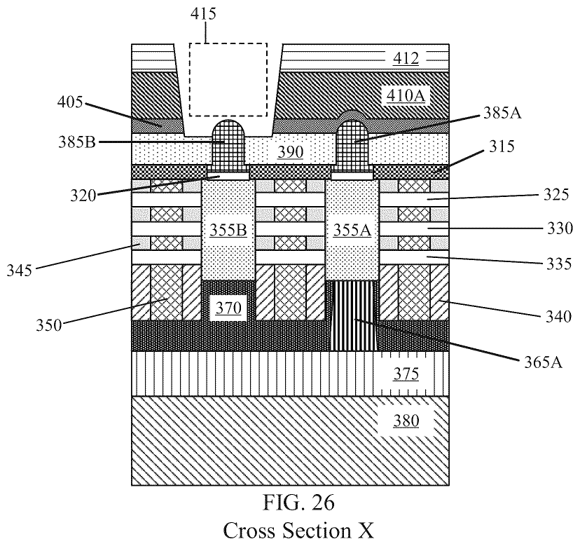

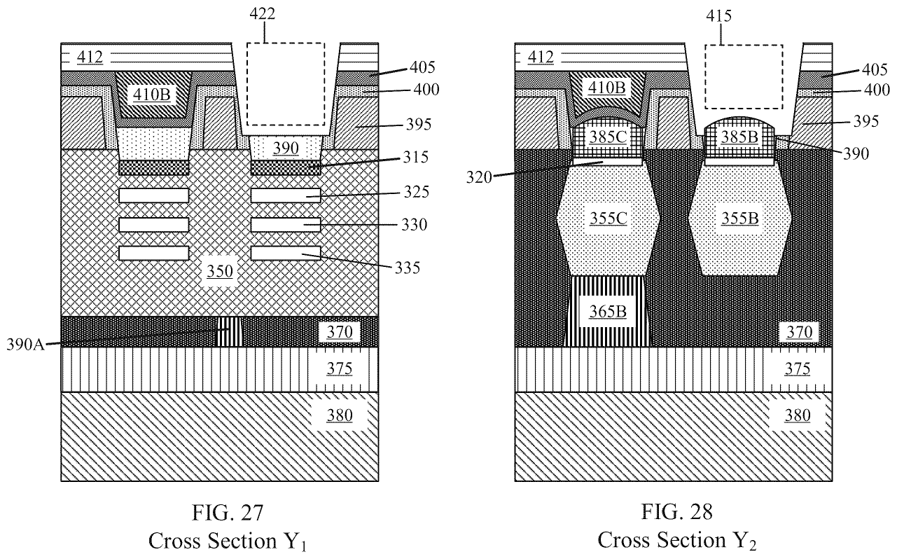

FIGS. 26-28 illustrate cross sections X, Y₁, and Y₂, respectively, of the plurality of nanodevices ND1, ND2 after the formation of the lithography mask layer 412, the first trench 415, and the second trench 422, in accordance with the embodiment of the present invention. In FIG. 26, the lithography mask layer 412 is deposited and then patterned directly atop the first conductive metal fill 410A to expose a portion of the underlying first conductive metal fill 410A. The exposed portion of the underlying first conductive metal fill 410A is etched by, for example, RIE to form the first trench 415. A bottom surface of the first trench 415 exposes a top surface and upper sidewalls of the second placeholder 385B. In FIG. 27, the lithography mask layer 412 is deposited and then patterned directly atop the backside thermal dissipation dielectric 405, the first conductive metal fill 410A, and the second conductive metal fill 410A to expose a portion of the underlying first conductive metal fill 410A and the backside thermal dissipation dielectric 405. The exposed portion of the underlying backside thermal dissipation dielectric 405, the first conductive metal fill 410A, and the STI liner 400 are etched by, for example, RIE to form the second trench 422. A bottom surface of the second trench 422 exposes a top surface of the BILD layer 390. In FIG. 28, the lithography mask layer 412 is deposited and then patterned directly atop the backside thermal dissipation dielectric 405, the first conductive metal fill 410A, and the second conductive metal fill 410A to expose a portion of the underlying first conductive metal fill 410A and the backside thermal dissipation dielectric 405. The exposed portion of the underlying backside thermal dissipation dielectric 405, the first conductive metal fill 410A, the STI liner 400, and the STI region 395 are etched by, for example, RIE to form the first trench 415. A bottom surface of the first trench 415 exposes a top surface and upper sidewalls of the second placeholder 385B. In FIGS. 26-28, the lithography mask layer 412 is formed by depositing, for example, an OPL material in a spin-on coating process.

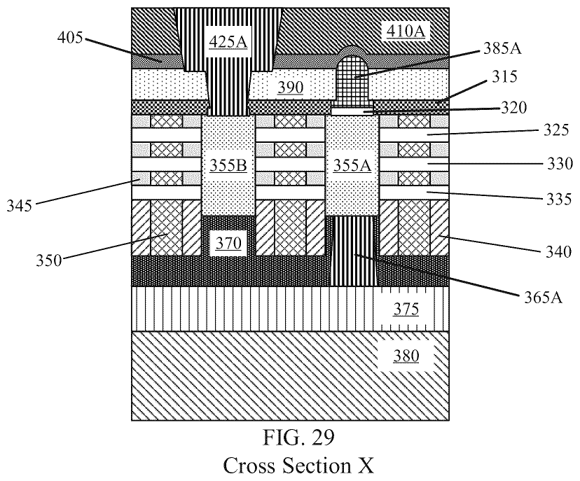

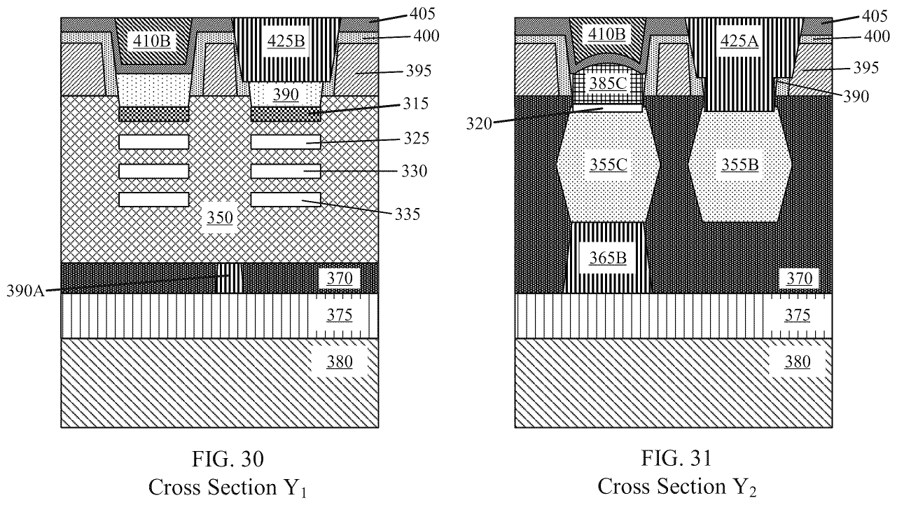

FIGS. 29-31 illustrate cross sections X, Y₁, and Y₂, respectively, of the plurality of nanodevices ND1, ND2 after the formation of the first backside source/drain contact 425A and the second backside source/drain contact 425B, in accordance with the embodiment of the present invention. The lithography mask layer 412 (FIGS. 26-28) and the second placeholder 385B (FIGS. 26 and 28) are removed. The first trench 415 (FIGS. 26 and 28) and the second trench 422 (FIG. 27) are filled with the conductive metal (e.g., including a silicide liner, such as Ni, Ti, NiPt, an adhesion metal liner, such as TiN and conductive metal fill, such as W, Co, or Ru) to form the first backside source/drain contact 425A and the second backside source/drain contact 425B. In FIGS. 29 and 31, the first backside source/drain contact 425A is located directly atop the second source/drain 355B. In FIG. 30, the second backside source/drain contact 425B is located directly atop the BILD layer 390.

The first conductive metal fill 410A is in direct contact with a backside surface of the backside thermal dissipation dielectric 405. The first conductive metal fill 410A is flush with a single horizontal backside surface of the first backside source/drain contact 425A. The thermal dissipation dielectric 405 and the first conductive metal fill 410A are in direct contact with the sidewalls of the first backside source/drain contact 425A.

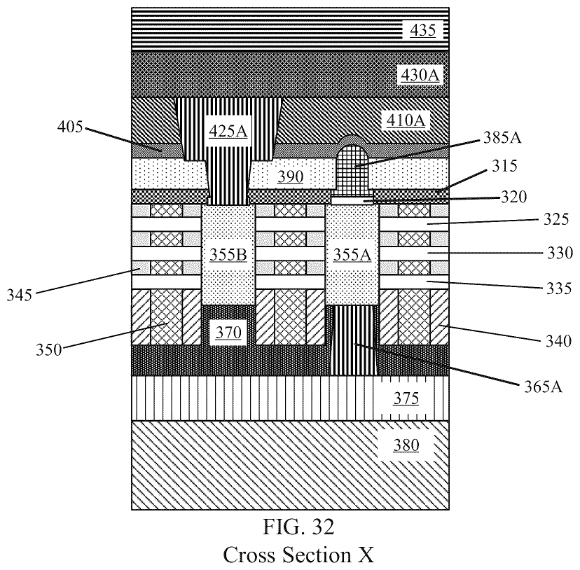

FIGS. 32-34 illustrate cross sections X, Y₁, and Y₂, respectively, of the plurality of nanodevices ND1, ND2 after the formation of the first BPR 430A, the second BPR 430B, the additional BILD layer 440, and the BSPDN 435, in accordance with the embodiment of the present invention. The first BPR 430A and the second BPR 430B are patterned using conventional lithography and etching processes, followed by metallization (e.g., Cu, Co or Ru fill with adhesion liner such as TiN).

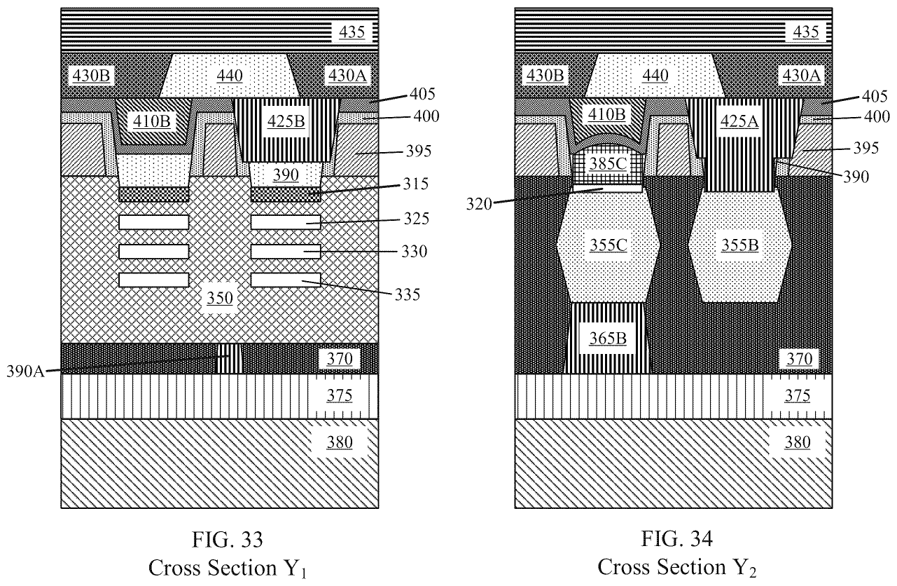

In FIG. 32, the first BPR 430A is formed directly atop the first conductive metal fill 410A and the first backside source/drain contact 425A. A top surface of the first backside source/drain contact 425A is connected to the first BPR 430A. In FIG. 33, the additional BILD layer 440 is deposited directly atop the backside thermal dissipation dielectric 405, the second conductive metal fill 410B, and the second backside source/drain contact 425B. The first BPR 430A is formed directly atop the backside thermal dissipation dielectric 405 and the second backside source/drain contact 425B. A bottom surface of the first BPR 430A is in direct contact with the backside thermal dissipation dielectric 405 and the second backside source/drain contact 425B. The second BPR 430B is formed directly atop the backside thermal dissipation dielectric 405 and the second conductive metal fill 410B. A bottom surface of the second BPR 430B is in direct contact with the backside thermal dissipation dielectric 405 and the second conductive metal fill 410B. In FIG. 34, the additional BILD layer 440 is deposited directly atop the backside thermal dissipation dielectric 405, the first backside source/drain contact 425A, and the second conductive metal fill 410B. The first BPR 430A is formed directly atop the backside thermal dissipation dielectric 405 and the first backside source/drain contact 425A. A bottom surface of the first BPR 430A is in direct contact with the backside thermal dissipation dielectric 405 and the first backside source/drain contact 425A. The second BPR 430B is formed directly atop the backside thermal dissipation dielectric 405 and the second conductive metal fill 410B. A bottom surface of the second BPR 430B is in direct contact with the backside thermal dissipation dielectric 405 and the second conductive metal fill 410B.

In FIG. 32, the BSPDN 435 is formed directly atop the first BPR 430A. In FIGS. 33-34, the BSPDN 435 is formed directly atop the first BPR 430A, the second BPR 430B, and the additional BILD layer 440.

The first BPR 430A is connected to a backside surface of the first conductive metal fill 410A and the second BPR 430B is connected to a backside surface of the second conductive metal fill 410B.

The BILD layer 190 is in direct contact with the first portion of the sidewalls of the first placeholder 185A. The BILD layer 190 is comprised of a first dielectric material. The first dielectric material may be, for example, Silicon oxycarbide. The backside thermal dissipation dielectric 205 is in direct contact with the backside surface of the BILD layer 190. The backside thermal dissipation dielectric 205 is comprised of a second dielectric material. The second dielectric material may be, for example, Aluminum nitride. The backside thermal dissipation dielectric 205 may be an Aluminum nitride dielectric fill.

The BILD layer 390 is in direct contact with the first portion of the sidewalls of the first placeholder 385A. The BILD layer 390 is comprised of a first dielectric material. The first dielectric material may be, for example, Silicon oxycarbide. The backside thermal dissipation dielectric 405 is in direct contact with the backside surface of the BILD layer 390. The backside thermal dissipation dielectric 405 is comprised of a second dielectric material. The second dielectric material may be, for example, Aluminum nitride. The backside thermal dissipation dielectric 405 may be an Aluminum nitride dielectric liner. The first conductive metal fill 410A is in direct contact with the backside surface of the backside thermal dissipation dielectric 405. The backside thermal dissipation dielectric 405 and the first conductive metal fill 410A are in direct contact with the sidewalls of the first backside source/drain contact 425A.

It may be appreciated that FIGS. 1-34 provide only an illustration of one implementation and do not imply any limitations with regard to how different embodiments may be implemented. Many modifications to the depicted environments may be made based on design and implementation requirements.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first nanodevice including a plurality of first transistors, wherein the first nanodevice includes a first placeholder;
a backside interlayer dielectric (BILD) layer in direct contact with a first portion of sidewalls of the first placeholder, wherein the BILD layer is comprised of a first dielectric material; and
a backside thermal dissipation dielectric in direct contact with a backside surface of the BILD layer, wherein the backside thermal dissipation dielectric is comprised of a second dielectric material.

2. The semiconductor device of claim 1, wherein the first dielectric material is Silicon oxycarbide and the second dielectric material is Aluminum nitride.

3. The semiconductor device of claim 2, wherein the backside thermal dissipation dielectric is in direct contact with a second portion of the sidewalls of the first placeholder and a backside surface of the first placeholder.

4. The semiconductor device of claim 3, further comprising:
an underlying silicon (Si) layer in direct contact with a frontside surface of the first placeholder.

5. The semiconductor device of claim 4, wherein the first placeholder progressively narrows from the frontside surface of the first placeholder to the backside surface of the first placeholder.

6. The semiconductor device of claim 5, further comprising:
a first source/drain in direct contact with a frontside surface of the underlying Si layer.

7. The semiconductor device of claim 6, further comprising:
a first source/drain contact connected to a frontside surface of the first source/drain; and
a back-end-of-line (BEOL) layer in direct contact with a frontside surface of the first source/drain contact, wherein the first source/drain is electrically connected to the BEOL layer via the first source/drain contact.

8. A semiconductor device comprising:
a first nanodevice including a plurality of first transistors, wherein the first nanodevice includes a first placeholder;
a second nanodevice including a plurality of second transistors, wherein the second nanodevice is located adjacent to and parallel to the first nanodevice, wherein the second nanodevice includes a second placeholder;
a BILD layer in direct contact with a first portion of sidewalls of the first placeholder, wherein the BILD layer is comprised of a first dielectric material; and
a backside thermal dissipation dielectric in direct contact with a backside surface of the BILD layer, wherein the backside thermal dissipation dielectric is comprised of a second dielectric material.

9. The semiconductor device of claim 8, wherein the first dielectric material is Silicon oxycarbide and the second dielectric material is Aluminum nitride.

10. The semiconductor device of claim 9, wherein the backside thermal dissipation dielectric is in direct contact with a second portion of the sidewalls of the first placeholder, a backside surface of the first placeholder, and a backside surface of the second placeholder.

11. The semiconductor device of claim 10, further comprising:
an underlying Si layer in direct contact with a frontside surface of the first placeholder and the second placeholder.

12. The semiconductor device of claim 11, wherein the first placeholder and the second placeholder progressively narrow from the frontside surface of the first placeholder and the second placeholder to the backside surface of the first placeholder and the second placeholder, respectively.

13. The semiconductor device of claim 12, further comprising:
a first source/drain and a second source/drain in direct contact with a frontside surface of the underlying Si layer.

14. The semiconductor device of claim 13, further comprising:
a first source/drain contact and a second source/drain contact connected to a frontside surface of the first source/drain and the second source/drain, respectively; and
a BEOL layer in direct contact with a frontside surface of the first source/drain contact and the second source/drain contact, wherein the first source/drain and the second source/drain are electrically connected to the BEOL layer via the first source/drain contact and the second source/drain contact, respectively.

15. A semiconductor device comprising:
a first nanodevice including a plurality of first transistors, wherein the first nanodevice includes a first placeholder;
a second nanodevice including a plurality of second transistors, wherein the second nanodevice is located adjacent to and parallel to the first nanodevice, wherein the second nanodevice includes a second placeholder;
a BILD layer in direct contact with a first portion of sidewalls of the first placeholder, wherein the BILD layer is comprised of a first dielectric material;
a backside thermal dissipation dielectric in direct contact with a backside surface of the BILD layer, wherein the backside thermal dissipation dielectric is comprised of a second dielectric material; and
a backside source/drain contact having two separate horizontal frontside surfaces, wherein a first horizontal frontside surface of the two separate horizontal frontside surfaces is in direct contact with the backside surface of the BILD layer.

16. The semiconductor device of claim 15, wherein the first dielectric material is Silicon oxycarbide and the second dielectric material is Aluminum nitride.

17. The semiconductor device of claim 16, further comprising:
a backside power rail (BPR) in direct contact with a backside surface of the backside thermal dissipation dielectric, wherein the backside thermal dissipation dielectric is flush with a single horizontal backside surface of the backside source/drain contact.

18. The semiconductor device of claim 16, further comprising:
a conductive metal fill in direct contact with a backside surface of the backside thermal dissipation dielectric, wherein the conductive metal fill is flush with a single horizontal backside surface of the backside source/drain contact.

19. The semiconductor device of claim 18, further comprising:
a BPR connected to a backside surface of the conductive metal fill.

20. The semiconductor device of claim 19, wherein the backside thermal dissipation dielectric and the conductive metal fill are in direct contact with sidewalls of the backside source/drain contact.
